(19) United States
(12) Patent Application Publication
(10) Pub. No.: US 2023/0178631 A1
(43) Pub. Date: Jun. 8, 2023

(54) METHODS OF MANUFACTURING SEMICONDUCTOR STRUCTURE

(71) Applicant: ENKRIS SEMICONDUCTOR, INC., Suzhou, Jiangsu (CN)

(72) Inventors: Kai Cheng, Suzhou, Jiangsu (CN); Peng Xiang, Suzhou, Jiangsu (CN)

(73) Assignee: ENKRIS SEMICONDUCTOR, INC., Suzhou, Jiangsu (CN)

(21) Appl. No.: 17/925,299

(22) PCT Filed: Sep. 23, 2020
(86) PCT No.: PCT/CN2020/117158

§ 371 Date: Nov. 14, 2022

(51) Int. Cl. H01L 29/66; H01L 21/265

(52) U.S. Cl. CPC H01L 29/66462; H01L 21/26506

(57) ABSTRACT

Disclosed is a method of manufacturing a semiconductor structure, including: providing a silicon substrate (10), epitaxially growing a functional layer (11) on an upper surface of the silicon substrate, where a material of the functional layer includes a group-III-nitride-based material; implanting ions into an interface between the upper surface of silicon substrate and the functional layer to introduce defects to the interface; or implanting, before epitaxially growing the functional layer, ions to the upper surface of the silicon substrate to introduce defects to the interface.

### CROSS-REFERENCE TO RELATED APPLICATIONS

This application is a U.S. National Phase of PCT Application No. PCT/CN2020/117158 (filed 23 Sep. 2020), the entire contents of which are incorporated herein by reference.

### TECHNICAL FIELD

The present disclosure relates to the field of semiconductor, and in particular, to methods of manufacturing a semiconductor structure.

### BACKGROUND

Wide-bandgap semiconductor materials, group III nitrides, as a typical representative of the third-generation semiconductor materials, have excellent characteristics of large wide-bandgap, high pressure resistance, high temperature resistance, high electron saturation velocity and drift velocity, and easy formation of high-quality heterostructures. The wide-bandgap semiconductor materials are ideal for manufacturing high temperature, high frequency, high power electronic devices.

For example, AlGaN/GaN heterojunction has a high concentration of two-dimensional electron gas (2 DEG) at an interface between AlGaN and GaN due to its strong spontaneous polarization and piezoelectric polarization, and AlGaN/GaN heterojunction is widely applied in semiconductor structures such as high electron mobility transistors (HEMTs).

Resistance at an interface between silicon substrate and GaN epitaxial layer is very low due to ions diffusion. The interface forms a conductive layer, which causes electric leakage of a device. For radio frequency device, the conductive layer also causes radio frequency loss, thereby reducing device performance. In view of this, it is necessary to provide a new method of manufacturing a semiconductor structure to solve the above technical problems.

### SUMMARY

According to the analysis of the inventor, the reason why channel current of the silicon-substrate-based semiconductor device is small and substrate heating is serious is that: at an interface between a silicon substrate and a group-III-nitride-based material, silicon atoms in the silicon substrate will diffuse to the group-III-nitride-based material, and group III atoms in the group-III-nitride-based material will diffuse to the silicon substrate, resulting in formation of a conductive layer at the interface between the silicon substrate and the group-III-nitride-based material, and the resistance of the conductive layer is very low; and the conductive layer will cause electric leakage of group-III-nitride-based material to the silicon substrate, thereby causing problems such as high radio frequency loss and low device performance of radio frequency devices.

Based on the above analysis, the purpose of the present disclosure is to improve electric leakage problem of the substrate.

In order to achieve the above purpose, the present disclosure provides a method of manufacturing a semiconductor structure, including:

providing a silicon substrate, and epitaxially growing a functional layer on an upper surface of the silicon substrate, where a material of the functional layer is a group-III-nitride-based material;

implanting ions into an interface between the silicon substrate and the functional layer to introduce defects to the interface; or implanting, before epitaxially growing the functional layer, ions into the upper surface of the silicon substrate to introduce defects to the interface.

In some embodiments, the implanted ions are group IV ions, group V ions, or group VI ions.

In some embodiments, the functional layer is a nucleation layer or a buffer layer.

In some embodiments, the functional layer includes a nucleation layer, a buffer layer and a heterojunction from bottom to top.

In some embodiments, the heterojunction includes a gate region, a source region and a drain region, where the source region and the drain region are located on both sides of the gate region, and the method further includes: forming a gate structure in the gate region, forming a source electrode in the source region, and forming a drain electrode in the drain region.

In some embodiments, the heterojunction includes a channel layer and a barrier layer from bottom to top.

In some embodiments, the heterojunction includes a gate region, a source region and a drain region, where the source region and the drain region are located on both sides of the gate region, and the method further includes: forming a gate structure in the gate region; forming a source electrode in the source region, the source electrode contacting the channel layer or the barrier layer; and forming a drain electrode in the drain region, the drain electrode contacting the channel layer or the barrier layer.

In some embodiments, the group V ions include at least one of nitrogen (N) ions, phosphorus (P) ions, arsenic (As) ions or antimony (Sb) ions.

In some embodiments, a material of the functional layer includes at least one of GaN, AlGaN, InGaN or AlInGaN.

In some embodiments, after ions implantation, annealing process is performed.

In some embodiments, a temperature of the annealing is greater than 300° C.

### BRIEF DESCRIPTION OF THE DRAWINGS

FIG. 1 is a flowchart of a method of manufacturing a semiconductor structure according to a first embodiment of the present disclosure;

FIG. 2 is a schematic view illustrating an intermediate structure corresponding to the processes of FIG. 1;

FIG. 3 is a flowchart of a method of manufacturing a semiconductor structure according to a second embodiment of the present disclosure;

FIG. 4 to FIG. 5 are schematic views illustrating intermediate structures corresponding to processes of FIG. 3;

FIG. 6 is a schematic view illustrating an intermediate structure corresponding to a method of manufacturing a semiconductor structure according to a third embodiment of the present disclosure;

FIG. 7 is a schematic view illustrating an intermediate structure corresponding to a method of manufacturing a semiconductor structure according to a fourth embodiment of the present disclosure; and

FIG. 8 is a schematic view illustrating an intermediate structure corresponding to a method of manufacturing a semiconductor structure according to a fifth embodiment of the present disclosure.

To facilitate the understanding of the present disclosure, all reference signs present in the present disclosure are listed below.

| | |
|---|---|
| [29] | Silicon substrate 10 |
| [30] | Functional layer 11 |
| [31] | Interface 12 |
| [32] | Nucleation layer 11a |
| [33] | Buffer layer 11b |
| [34] | Heterojunction 13 |
| [35] | Gate region 13a |
| [36] | Source region 13b |
| [37] | Drain region 13c |
| [38] | Gate structure 14a |
| [39] | Source electrode 14b |
| [40] | Drain electrode 14c |
| [41] | Channel layer 11c |
| [42] | Barrier layer 11d |

### DETAILED DESCRIPTION OF THE EMBODIMENTS

In order to make the above-mentioned objects, features and advantages of the present disclosure more obvious and understandable, embodiments of the present disclosure will be described in detail below with reference to the accompanying drawings.

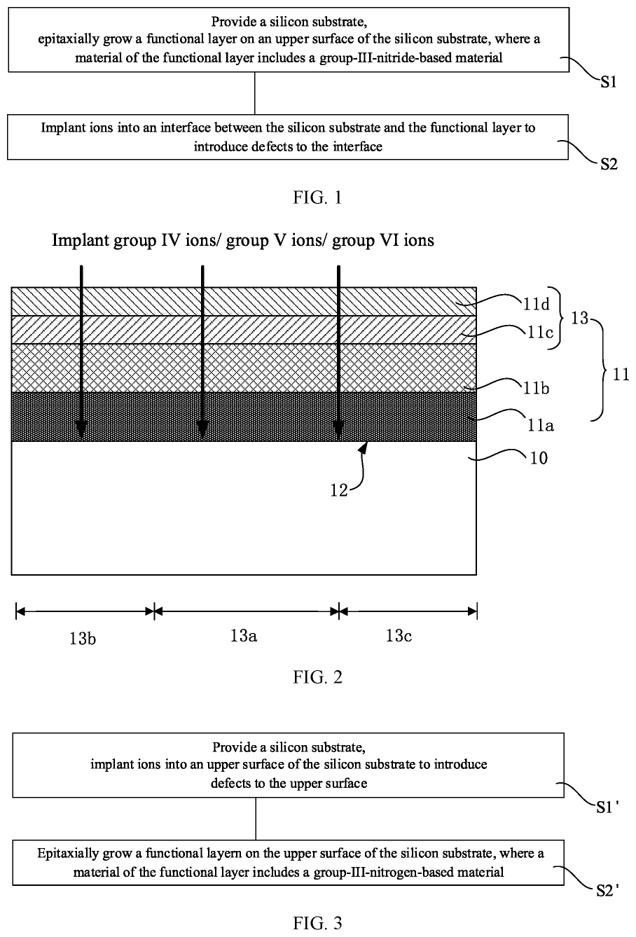

FIG. 1 is a flowchart of a method of manufacturing a semiconductor structure according to a first embodiment of the present disclosure; and FIG. 2 is a schematic view illustrating an intermediate structure corresponding to the processes of FIG. 1.

First, referring to step S1 in FIG. 1 and as shown in FIG. 2, a silicon substrate 10 is provided, and a functional layer 11 is epitaxially grown on an upper surface of the silicon substrate 10. A material of the functional layer 11 includes a group-III-nitride-based material.

A material of the silicon substrate 10 is monocrystalline silicon.

In this embodiment, as shown in FIG. 2, the functional layer 11 includes a nucleation layer 11a, a buffer layer 11b and a heterojunction 13 from bottom to top.

The heterojunction 13 can include a channel layer 11c and a barrier layer 11d from bottom to top. Two-dimensional electron gas or two-dimensional hole gas can be formed at an interface between the channel layer 11c and the barrier layer 11d. In some embodiments, the channel layer 11c is an intrinsic GaN layer, and the barrier layer 11d is an N-type AlGaN layer. In some embodiments, a material combination of the channel layer 11c and the barrier layer 11d can include GaN/AlN, GaN/InN, GaN/InAlGaN, GaAs/AlGaAs, GaN/InAlN or InN/InAlN. In addition to one channel layer 11c and one barrier layer 11d shown in FIG. 2, the channel layer 11c and the barrier layer 11d can also have a plurality of layers respectively, which are alternately distributed; or there are one channel layer 11c and two or more barrier layers 11d to form a multi-barrier structure.

It should be noted that, in the present disclosure, a certain material is represented by a chemical element, but molar ratios of respective chemical elements in the material are not limited. For example, in GaN material, gallium (Ga) element and nitrogen (N) element are included, but molar ratios of gallium element and nitrogen element are not limited; in AlGaN material, aluminum (Al) element, gallium (Ga) element and nitrogen (N) element are included, but respective molar ratios of aluminum element, gallium element and nitrogen element are not limited.

A source region 13b of the heterojunction 13 is used to form a source electrode 14b thereon, a drain region 13c of the heterojunction 13 is used to form a drain electrode 14c thereon, and a gate region 13a of the heterojunction 13 is used to form a gate structure 14a thereon.

A nucleation layer 11a and a buffer layer 11b are arranged from bottom to top between the heterojunction 13 and the substrate 10.

A material of the nucleation layer 11a can include, for example, AlGaN or the like. A material of the buffer layer 11b includes at least one of GaN, AlGaN, or AlInGaN. The nucleation layer 11a can alleviate problems of lattice mismatch and thermal mismatch between the substrate 10 and the epitaxially grown semiconductor layer, such as the channel layer 11c in the heterojunction 13, and the buffer layer 11b can reduce a dislocation density and defect density of the epitaxially grown semiconductor layer, and improve a crystal quality.

At the interface 12 between the silicon substrate 10 and the functional layer 11 of the group-III-nitride-based material, silicon atoms in the silicon substrate 10 will diffuse to the functional layer 11 of the group-III-nitride-based material, and group III atoms in the functional layer 11 of the group-III-nitride-based material will diffuse to the silicon substrate 10, resulting in the formation of a conductive layer at the interface 12 between the silicon substrate 10 and the functional layer 11 of the group-III-nitride-based material. When the channel of the semiconductor structure is turned on, due to the low resistance of the conductive layer, the functional layer 11 of the group-III-nitride-based material will electric leak electricity to the silicon substrate 10.

After that, referring to step S2 in FIG. 1 and as shown in FIG. 2, ions are implanted into the interface 12 between the silicon substrate 10 and the functional layer 11 to introduce defects to the interface 12.

The defects can capture free carriers in the conductive layer, reduce conductivity of the conductive layer, and increase resistance of the conductive layer, thereby alleviating the problem of electric leakage of functional layer 11 of the group-III-nitride-based material to the silicon substrate 10.

The implanted ions can include group IV ions, group V ions, or group VI ions. The group V ions can include at least one of nitrogen (N) ions, phosphorus (P) ions, arsenic (As) ions, or antimony (Sb) ions. The group IV ions can include at least one of carbon (C) ions, silicon (Si) ions, germanium (Ge) ions, or tin (Sn) ions. The group VI ions can include at least one of oxygen (O) ions, sulfur (S) ions, selenium (Se) ions, or tellurium (Te) ions.

In some embodiments, after ions implantation, an annealing process can also be performed. A temperature of the annealing is greater than 300° C. Annealing can make the defect distribution uniform, which is beneficial to capture free carriers in the conductive layer.

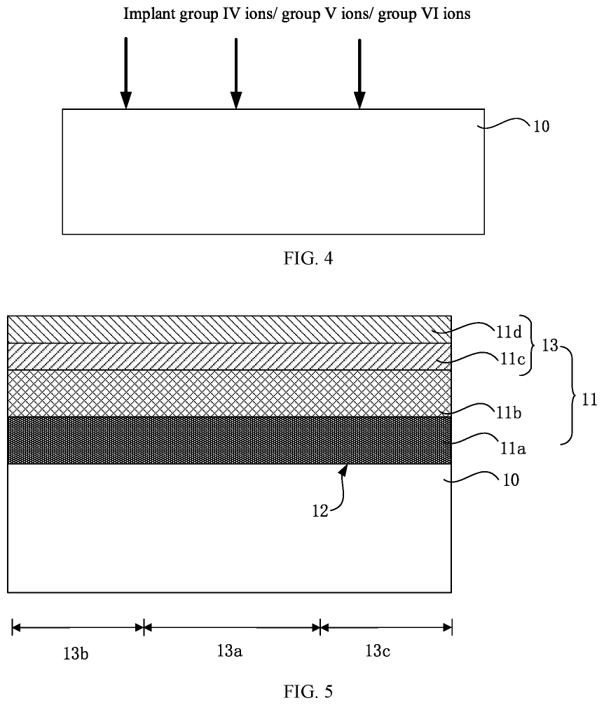

FIG. 3 is a flowchart of a method of manufacturing a semiconductor structure according to a second embodiment of the present disclosure; and FIG. 4 to FIG. 5 are schematic views illustrating intermediate structures corresponding to processes of FIG. 3.

Referring to FIG. 3, the method of manufacturing the semiconductor structure of the second embodiment is substantially the same as the method of manufacturing the semiconductor structure of the first embodiment, except that: at step S1′, as shown in FIG. 4, a silicon substrate 10 is provided, and ions are implanted into an upper surface of the silicon substrate 10 to introduce defects to the upper surface of the silicon substrate 10; at step S2′, referring to FIG. 5, a functional layer 11 is epitaxially grown on the upper surface of the silicon substrate 10, and a material of the functional layer 11 includes a group-III-nitrogen-based material. In other words, before epitaxially growing the functional layer 11, ions are implanted into the upper surface of the silicon substrate 10 to introduce defects to the upper surface.

For types and functions of implanted ions, reference can be made to the types and functions of implanted ions in the first embodiment.

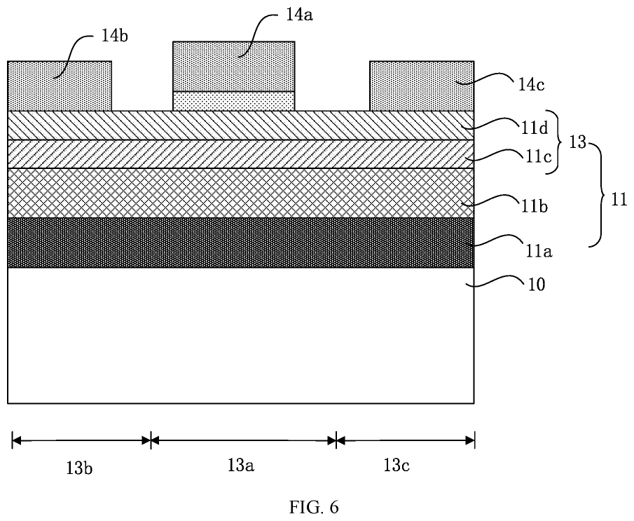

FIG. 6 is a schematic view illustrating an intermediate structure corresponding to a method of manufacturing a semiconductor structure according to a third embodiment of the present disclosure. Referring to FIG. 6, the method of manufacturing the semiconductor structure of the third embodiment is substantially the same as the method of manufacturing the semiconductor structures of the first and second embodiments, except that: the method further includes: forming a gate structure 14a in a gate region 13a; forming a source electrode 14b in the source region 13b, and forming a drain electrode 14c in the drain region 13c.

The gate structure 14a includes a gate insulating layer and a gate electrode from bottom to top.

In FIG. 6, the source electrode 14b and the drain electrode 14c are in contact with the barrier layer 11d, and ohmic contacts are formed between the source electrode 14b and the barrier layer 11d, and between the drain electrode 14c and the barrier layer 11d; Schottky contact is formed between the gate electrode and the barrier layer 11d through the gate insulating layer. The source electrode 14b, the drain electrode 14c, and the gate electrode can include metal, such as conductive materials, for example titanium (Ti)/aluminum (Al)/nickel (Ni)/aurum (Au), nickel (Ni)/aurum (Au), and the like.

In some embodiments, ohmic contacts can be formed between the source electrode 14b and the barrier layer 11d, and/or between the drain electrode 14c and the barrier layer 11d by using an N-type ion heavily doped layer. The N-type ion heavily doped layer enables the source electrode 14b and the source region 13a of the heterojunction 13, the drain electrode 14c and the drain region 13b of the heterojunction 13 to directly form an ohmic contact layer without high temperature annealing, and avoids a high temperature during the annealing process causing a performance of the heterojunction 13 to degrade and the electron mobility rate to decrease.

In some embodiments, at least one of the source region 13b or the drain region 13c of the heterojunction 13 can have an N-type ion heavily doped layer located thereon. The source region 13b of the heterojunction 13 without the N-type ion heavily doped layer and the source electrode 14b, or the drain region 13c of the heterojunction 13 without the N-type ion heavily doped layer and the drain electrode 14c, are annealed at high temperature to form an ohmic contact layer.

In the N-type ion heavily doped layer, the N-type ions can include at least one of silicon (Si) ions, germanium (Ge) ions, tin (Sn) ions, selenium (Se) ions or tellurium (Te) ions. For different N-type ions, a doping concentration can be greater than 1E19/cm³. The N-type ion heavily doped layer can be a group-III-nitride-based material, such as at least one of GaN, AlGaN, or AlInGaN.

In some embodiments, the gate insulating layer can also be replaced with a P-type semiconductor layer to form an enhancement mode HEMT.

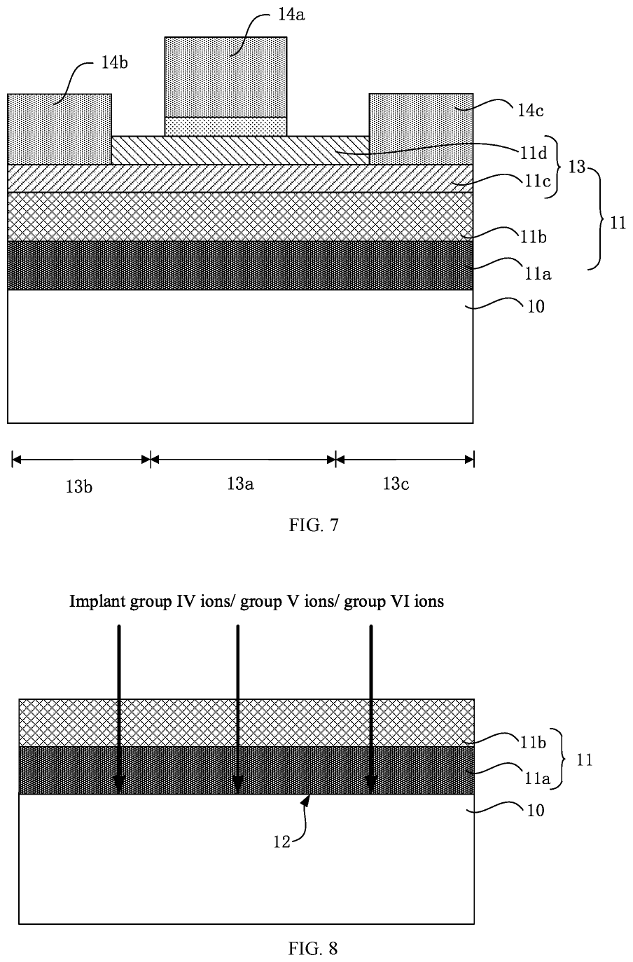

FIG. 7 is a schematic view illustrating an intermediate structure corresponding to a method of manufacturing a semiconductor structure according to a fourth embodiment of the present disclosure. Referring to FIG. 7, the method of manufacturing the semiconductor structure of the fourth embodiment is substantially the same as the method of manufacturing the semiconductor structure of the third embodiment, except that: the source electrode 14b and the drain electrode 14c are in contact with the channel layer 11c, and ohmic contacts are formed between the source electrode 14b and the channel layer 11c and between the drain electrode 14c and the channel layer 11c.

In some embodiments, ohmic contact can be formed between the source electrode 14b and the channel layer 11c and between the drain electrode 14c and the channel layer 11c by using an N-type ion heavily doped layer.

FIG. 8 is a schematic view illustrating an intermediate structure corresponding to a method of manufacturing a semiconductor structure according to a fifth embodiment of the present disclosure. Referring to FIG. 8, the method of manufacturing the semiconductor structure of the fifth embodiment is substantially the same as the method of manufacturing the semiconductor structure of first, second, third and fourth embodiments, except that: the functional layer 11 includes a nucleation layer 11a and a buffer layer 11b from bottom to top. In other words, ions implantation is performed after the buffer layer 11b is formed.

In some embodiments, after ions are implanted into the upper surface of the silicon substrate 10, the nucleation layer 11a and the buffer layer 11b can be epitaxially grown on the upper surface of the silicon substrate 10 in sequence.

After that, the heterojunction 13 can be formed on the buffer layer 11b, and the gate structure 14a, the source electrode 14b and the drain electrode 14c can be further formed on the heterojunction 13.

In some embodiments, the functional layer 11 can include only the buffer layer 11b. In other words, the nucleation layer 11a is omitted.

In some embodiments, the functional layer 11 can include only the nucleation layer 11a. In other words, after the nucleation layer 11a is formed, the ions implantation is preformed; or after ions are implanted into the upper surface of the silicon substrate 10, the nucleation layer 11a is epitaxially grown on the upper surface of the silicon substrate 10.

After that, the buffer layer 11b can be formed on the nucleation layer 11a, the heterojunction 13 can be formed on the buffer layer 11b, and the gate structure 14a, the source electrode 14b and the drain electrode 14c can be formed on the heterojunction 13.

Compared with the related art, the present disclosure has the following beneficial effects.

1) In the method of manufacturing the semiconductor structure according to the present disclosure, ions are implanted into the interface between the silicon substrate and the group-III-nitride-based material to introduce defects into the conductive layer of the interface; or before epitaxially growing the functional layer, ions are implanted into the upper surface of the silicon substrate to introduce defects into the conductive layer of the interface, such that free carriers in the conductive layer are captured by the defects, the conductivity of the conductive layer is reduced, and the resistance of the conductive layer is increased, thereby alleviating the problem of electric leakage of substrate.

2) In an alternative solution, the functional layer of the group-III-nitride-based material includes a) a nucleation layer or a buffer layer, or b) a nucleation layer, a buffer layer and a heterojunction from bottom to top. In other words, the ions can be implanted after the nucleation layer or the buffer layer is formed, or the ions can be implanted after the heterojunction is formed.

3) In an alternative solution, an annealing step is also performed after the ions implantation. Annealing can make the defect distribution uniform, which is beneficial to capture free carriers in the conductive layer.

Although the present disclosure discloses the above contents, the present disclosure is not limited thereto. Any one of ordinary skill in the art can make various variants and modifications to the present disclosure without departing from the spirit and scope of the present disclosure. Therefore, the protection scope of the present disclosure should be set forth by the appended claims.

1. A method of manufacturing a semiconductor structure, comprising:
providing a silicon substrate, epitaxially growing a functional layer on an upper surface of the silicon substrate, wherein a material of the functional layer comprises a group-III-nitride-based material; and
implanting ions into an interface between the silicon substrate and the functional layer to introduce defects to the interface; or implanting, before epitaxially growing the functional layer, ions into the upper surface of the silicon substrate to introduce defects to the interface.

2. The method of manufacturing the semiconductor structure according to claim 1, wherein the implanted ions comprise group IV ions, group V ions, or group VI ions.

3. The method of manufacturing the semiconductor structure according to claim 1, wherein the functional layer is a nucleation layer or a buffer layer.

4. The method of manufacturing the semiconductor structure according to claim 1, wherein the functional layer comprises a nucleation layer, a buffer layer and a heterojunction from bottom to top.

5. The method of manufacturing the semiconductor structure according to claim 4, wherein
the heterojunction comprises a gate region, a source region and a drain region, wherein the source region and the drain region are located on both sides of the gate region; and
the method further comprises:
forming a gate structure in the gate region;
forming a source electrode in the source region; and
forming a drain electrode in the drain region.

6. The method of manufacturing the semiconductor structure according to claim 4, wherein the heterojunction comprises a channel layer and a barrier layer from bottom to top.

7. The method of manufacturing the semiconductor structure according to claim 6, wherein the heterojunction comprises a gate region, a source region and a drain region, wherein the source region and the drain region located on both sides of the gate region; and
the method further comprises:
forming a gate structure in the gate region;
forming a source electrode in the source region, the source electrode contacting the channel layer or the barrier layer; and
forming a drain electrode in the drain region, the drain electrode contacting the channel layer or the barrier layer.

8. The method of manufacturing the semiconductor structure according to claim 2, wherein the group V ions comprise at least one of nitrogen ions, phosphorus ions, arsenic ions or antimony ions.

9. The method of manufacturing the semiconductor structure according to claim 1, wherein a material of the functional layer comprises at least one of GaN, AlGaN, InGaN, or AlInGaN.

10. The method of manufacturing the semiconductor structure according to claim 1, wherein after ions implantation, annealing process is performed.

11. The method of manufacturing the semiconductor structure according to claim 10, wherein a temperature of the annealing is greater than 300° C.

12. The method of manufacturing the semiconductor structure according to claim 2, wherein
the group IV ions comprise at least one of carbon ions, silicon ions, germanium ions, or tin ions; or
the group VI ions comprise at least one of oxygen ions, sulfur ions, selenium ions, or tellurium ions.

13. The method of manufacturing the semiconductor structure according to claim 6, wherein a structure of the heterojunction comprises at least one of:
one channel layer and one barrier layer;
a plurality of channel layers and a plurality of barrier layers distributed alternately; or
one channel layer and two or more barrier layers to form a multi-barrier structure.

14. The method of manufacturing the semiconductor structure according to claim 7, wherein the gate structure comprises a gate insulating layer and a gate electrode from bottom to top.

15. The method of manufacturing the semiconductor structure according to claim 14, wherein the gate insulating layer is a P-type semiconductor layer.

16. The method of manufacturing the semiconductor structure according to claim 7, wherein the method comprises at least one of:
forming ohmic contacts between the source electrode and the channel layer or the barrier layer by using an N-type ion heavily doped layer, or
forming ohmic contacts between the drain electrode and the channel layer or the barrier layer by using an N-type ion heavily doped layer.

17. The method of manufacturing the semiconductor structure according to claim 16, wherein doping concentrations of different N-type ions in the N-type ion heavily doped layer are greater than 1E19/cm³.

18. The method of manufacturing the semiconductor structure according to claim 16, wherein N-type ions of the N-type ion heavily doped layer comprises at least one of silicon ions, germanium ions, tin ions, selenium ions or tellurium ions.

19. The method of manufacturing the semiconductor structure according to claim 16, wherein a material of the N-type ion heavily doped layer is a group-III-nitride-based material.
